(19) United States
(12) Patent Application Publication
(10) Pub. No.: US 2013/0285087 A1
(43) Pub. Date: Oct. 31, 2013

(54) LIGHT EMITTING DEVICE AND MANUFACTURING METHOD THEREOF

(71) Applicants: Horng-Jou WANG, Taoyuan Hsien (TW); Shao-Yu Chen, Taoyuan Hsien (TW); Chia-Hua Liu, Taoyuan Hsien (TW)

(72) Inventors: Horng-Jou WANG, Taoyuan Hsien (TW); Shao-Yu Chen, Taoyuan Hsien (TW); Chia-Hua Liu, Taoyuan Hsien (TW)

(21) Appl. No.: 13/530,859

(22) Filed: Jun. 22, 2012

(30) Foreign Application Priority Data
Apr. 27, 2012 (TW) 101115055

(51) Int. Cl. H01L 33/50; H01L 33/60

(52) U.S. Cl. 257/98; 438/29; 257/E33.072; 257/E33.062

(57) ABSTRACT

A light emitting device and manufacturing method thereof are disclosed. The light emitting device includes a substrate, a LED die, a first transparent layer, an optical wavelength conversion layer and a second transparent layer. The substrate has a die glue part. The LED die is disposed on the die glue part and has a base which is made of a transparent material. The first transparent layer is disposed on the side surface of the LED die. The optical wavelength conversion layer is evenly formed on the first transparent layer and the LED die. The second transparent layer is formed on the optical wavelength conversion layer.

### CROSS REFERENCE TO RELATED APPLICATIONS

This Non-provisional application claims priority under 35 U.S.C. §119(a) on Patent Application No(s). 101115055 filed in Taiwan, Republic of China on Apr. 27, 2012, the entire contents of which are hereby incorporated by reference.

### BACKGROUND OF THE INVENTION

1. Field of Invention

The present invention relates to a light emitting device and a manufacturing method thereof, and in particular, to a light emitting device having a LED die with a transparent base and a manufacturing method thereof.

2. Related Art

Using blue light LED to excite yellow phosphor so as to achieve the desired colorful light mixing effect is one of the most common LED technologies. The optical properties of this technology are deeply affected by the phosphor coating during the packaging process of LED.

FIG. 1 is a schematic diagram showing a conventional light emitting device 1, which includes a substrate 11, a LED die 12, a die glue portion 13, a phosphor layer 14, and a covering layer 15. The die glue portion 13 is disposed at the center of the substrate 11, and the LED die 12 is disposed on the die glue portion 13. The phosphor layer 14 covers the side surface and top surface of the LED die 12. The covering layer 15 covers on the phosphor layer 14.

Due to the material properties of the phosphor layer 14 (e.g. the liquid surface tension) and the geometry limitation existing between the side surface of the LED die 12 and the contact surface of the die glue portion 13 (e.g. relatively perpendicular configuration), the part of the phosphor layer 14 covering the side surface of the LED die 12 usually has an uneven thickness. This uneven thickness can cause the bad color property after light mixing, and moreover, result in the undesired color halo as the LED is applied to lamps.

When the part of the phosphor layer 14 covering the side surface of the LED die 12 has the uneven thickness, the front light beam and the lateral light beam passing through the phosphor layer 14 have different light paths so that the light beams can not be evenly mixed. This will greatly decrease the uniformity and unity of the optical color expression of the light emitting device 1.

### SUMMARY OF THE INVENTION

In view of the foregoing subject, an objective of the present invention is to provide a light emitting device and a manufacturing method thereof, which is suitable for the LED die with a transparent base and have better uniformity and unity of the optical color.

To achieve the above objective, the present invention discloses a light emitting device including a substrate, a LED die, a first transparent layer, an optical wavelength conversion layer and a second transparent layer. The substrate has a die glue part. The LED die is disposed on the die glue part and has a base which is made of a transparent material. The first transparent layer is disposed on the side surface of the LED die. The optical wavelength conversion layer is evenly formed on the first transparent layer and the LED die. The second transparent layer is formed on the optical wavelength conversion layer.

To achieve the above objective, the present invention also discloses a manufacturing method of a light emitting device. The method includes the steps of: providing a substrate having a die glue part; disposing a LED die on the die glue part, wherein the LED die has a base which is made of a transparent material; forming a first transparent layer on side surface of the LED die; evenly forming an optical wavelength conversion layer on the first transparent layer and the LED die; and forming a second transparent layer on the optical wavelength conversion layer.

As mentioned above, the light emitting device of the invention has a first transparent layer for covering the side surface of the LED die so that the optical wavelength conversion layer can cover the first transparent layer and the top surface of the LED die with an even thickness. Thus, after the light beams emitted from the front and lateral sides of the LED die pass through the optical wavelength conversion layer, they can be well mixed to provide good optical light mixing effect and better uniformity and unity of the optical color expression.

Furthermore, the manufacturing method of the light emitting device of the invention is to form the first transparent layer on the side surface of the LED die in advance so that the optical wavelength conversion layer can be formed on the first transparent layer and the top surface of the LED die with an even thickness. Thus, after the front and lateral light beams emitted from the LED die pass through the optical wavelength conversion layer, they can well mixed to provide good light mixing effect, thereby solving the problems of color uniformity and unity after light mixing.

### BRIEF DESCRIPTION OF THE DRAWINGS

The present invention will become more fully understood from the subsequent detailed description and accompanying drawings, which are given by way of illustration only, and thus are not limitative of the present invention, and wherein:

FIG. 1 is a schematic diagram showing a conventional light emitting device;

FIG. 2 is a schematic diagram of a light emitting device according to a preferred embodiment of the invention;

FIGS. 3A and 3B are schematic diagrams showing the LED die of different aspects of the invention;

FIGS. 4A to 4C are schematic diagrams showing the first transparent layer covering the LED die of different aspects of the invention;

FIGS. 5A to 5C are schematic diagrams showing the second transparent layer of different aspects of the invention; and

FIG. 6 is a flow chart of a manufacturing method of a light emitting device according to a preferred embodiment of the invention.

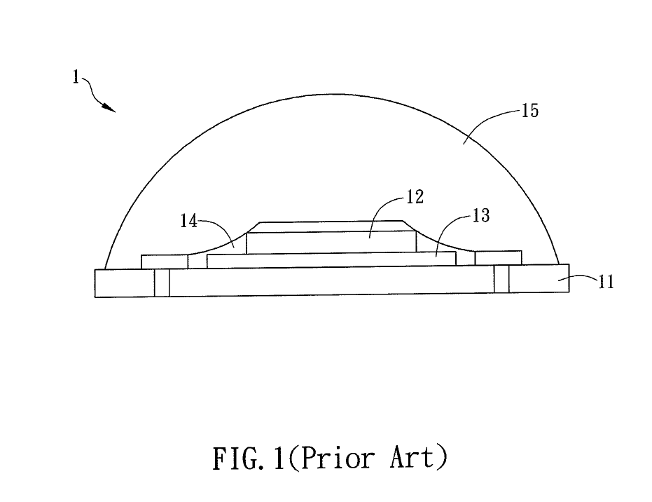

### DETAILED DESCRIPTION OF THE INVENTION

The present invention will be apparent from the following detailed description, which proceeds with reference to the accompanying drawings, wherein the same references relate to the same elements.

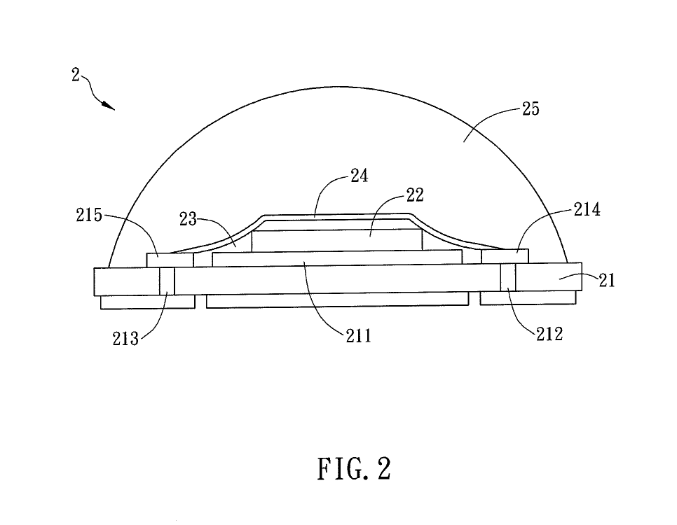

FIG. 2 is a schematic diagram of a light emitting device 2 according to a preferred embodiment of the invention. The light emitting device 2 includes a substrate 21, a LED die 22, a first transparent layer 23, an optical wavelength conversion layer 24 and a second transparent layer. The substrate 21 has a die glue part 211 located at the center of the top surface of the substrate 21. The LED die 22 is disposed on the die glue part 211. The first transparent layer 23 is disposed on the side surface and top surface of the LED die 22. The optical wavelength conversion layer 24 is evenly covered on the first transparent layer 23. The second transparent layer 25 is covered on the optical wavelength conversion layer 24.

The substrate 24 further has two electrode connecting elements 212 and 213, a first electrode 214 and a second electrode 215. The first electrode 214 and the second electrode 215 are disposed on the substrate 21 and located at two sides of the die glue part 211. The LED die 22 is electrically connected with the first electrode 214 and the second electrode 215. The electrode connecting elements 212 and 213 pass through the substrate 21 for electrically connecting the first electrode 214 and the second electrode 215 to the bottom surface of the substrate 21. The material of the substrate 21 can include aluminum oxide, aluminum nitride, silicon carbide, silicon substrate, copper metal or alloy, aluminum metal or alloy, a metal-core printed circuit board, a glass fiber epoxy substrate (e.g. flame retardant type (FR4 or FR5) substrate), or ceramic material (e.g. direct bond copper ceramic material), etc. for allowing the LED die 22 to be glued on the substrate.

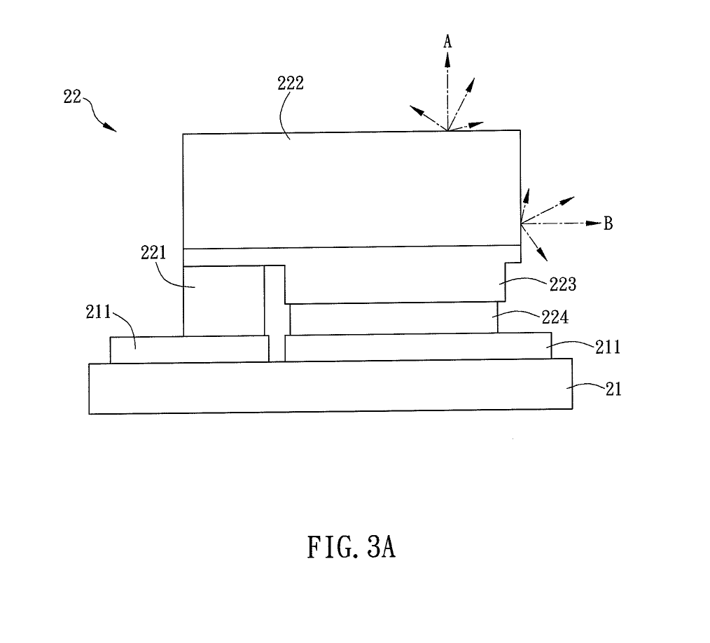

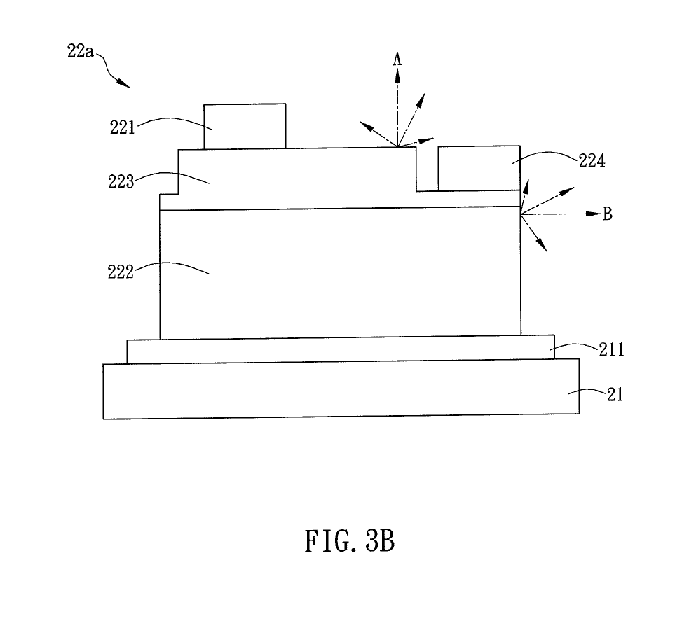

FIGS. 3A and 3B are schematic diagrams showing the LED die 22 of different aspects of the invention. In order to make the following description more easily understanding, the displayed components may not represent the real scales, and are used for reference instead of limitation. Of course, the structure of the LED die 22 of the invention can be optionally changed based on the application and lamps in use. As shown in FIG. 3A, the LED die 22 further includes a first electrode 221, a base 222, an epitaxial layer 223 and a second electrode 224. The first electrode 221 and the second electrode 224 are disposed on the bottom surface of the epitaxial layer 223. This configuration is a flip-chip or flip-chip-like structure, which is an example but not for limitation.

The base 222 is disposed on the epitaxial layer 223 and is made of a transparent material such as sapphire, aluminum oxide, glass, silicon dioxide, or silicon carbide. When the LED die 22 emits (visible or invisible) light, the front light beam A and the lateral light beam B are generated simultaneously because the base 222 is made of the transparent material. In this case, the arrangement of the optical wavelength conversion layer 24 can affect the light mixing effect and color expression of the light emitting device, which will be further described hereinafter.

With reference to FIG. 3B, in another embodiment, the LED die 22a has a horizontal die structure. That is, the first electrode 221 and the second electrode 224 are disposed on the top surface of the epitaxial layer 223. The base 222 of the LED die 22a is attached to the die glue part 211.

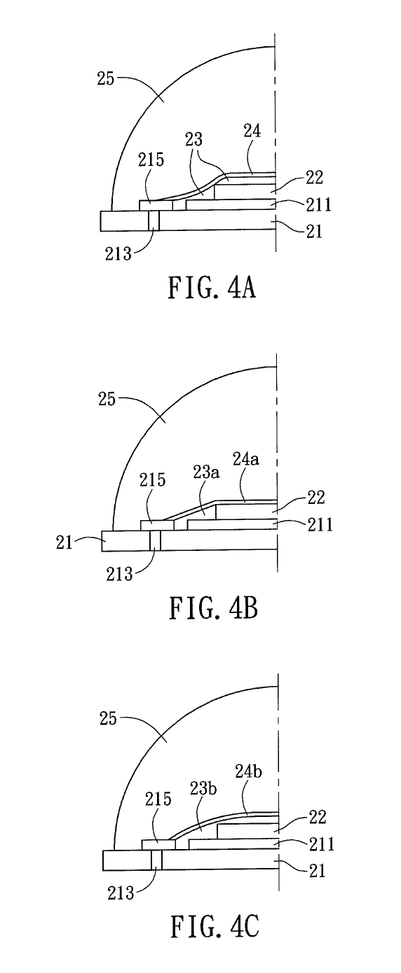

FIGS. 4A to 4C are schematic diagrams showing the first transparent layer of the invention covering the LED die of different aspects. In FIGS. 4A to 4C, some components are not shown for clarifying the following description, and they are for illustrations only and not to limit the invention. The first transparent layer 23 covers the side surface of the LED die 22. To be noted, the aspect and covering type of the first transparent layer 23 are not limited to the above example, and they can be modified according to the actual needs. As shown in FIG. 4A, the first transparent layer 23 covers on the LED die 22, and has a part covering the side of the LED die 22 in a triangle or triangle-like cross-sectional shape. In addition, the optical wavelength conversion layer 24 evenly covers the first transparent layer 23.

As shown in FIG. 4B, the boundary of the first transparent layer 23a comprises the side surface of the LED die 22 and the top surface of the substrate 21, thereby forming a triangle or triangle-like cross-sectional shape on the side of the LED die 22. Thus, the optical wavelength conversion layer 24a can evenly cover the first transparent layer 23a and the LED die 22.

As shown in FIG. 4C, the boundary of the first transparent layer 23b comprises the outer surface and the bottom surface of the LED die 22, thereby forming a trapezoid or trapezoid-like cross-sectional shape on the side and top surfaces of the LED die 22. Similarly, the optical wavelength conversion layer 24b can evenly cover the first transparent layer 23b. The first transparent layer can comprise silicon gel, epoxy, a mixture of silicon gel and epoxy, a polymer material, glass, or a transparent material. The optical wavelength conversion layer can further comprise optical wavelength conversion particles, which comprise YAG (yttrium aluminum garnet) phosphor, silicate phosphor, TAG (terbium, aluminum garnet) phosphor, oxide phosphor, nitride phosphor, aluminum oxide phosphor, or any other phosphor or material with optical wavelength conversion function.

With reference to FIGS. 3A and 3B, since the base 222 is made of transparent material, the light emitted from the LED die 22 can form the front light beam A and the lateral light beam B. Besides, the first transparent layer 23 covers the side and top surfaces of the LED die 22, so that the successively formed optical wavelength conversion layer 24 can evenly cover on the first transparent layer 23 and the LED die 22. Thus, the optical path lengths of the front light beam A and the lateral light beam B passing the optical wavelength conversion layer 24 are even, thereby solving the problem of bad color uniformity and unity caused by the difference of optical path lengths of the front light beam A and the lateral light beam B passing the conventional phosphor layer (optical wavelength conversion layer) with uneven thickness. Accordingly, the invention can achieve good light mixing effect. Furthermore, the conventional problem of light halo can be prevented. Besides, since the base 222 of the LED die 22 is made of transparent material, the material cost of the LED die 22 can have more competitive than the LED die with the base made of non-transparent material (e.g. silicon carbide or copper).

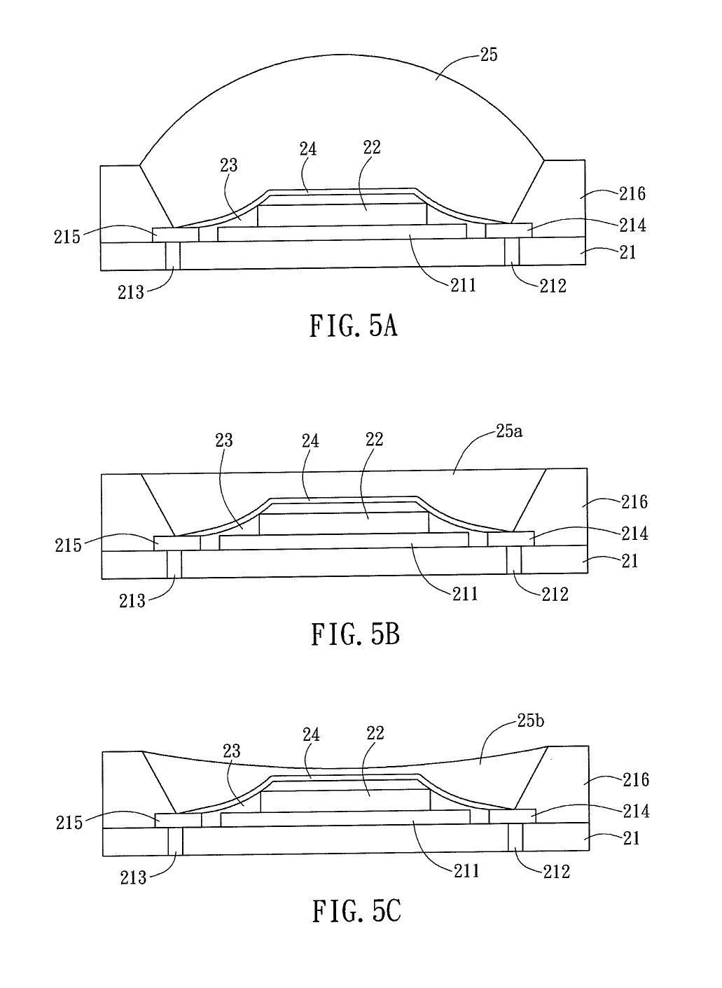

FIGS. 5A to 5C are schematic diagrams showing the second transparent layer 25 of different aspects of the invention. In this case, the substrate 21 further comprises a reflective structure 216 located at the sides of the top surface of the substrate 21 for further condensing or dispersing the light emitted from the LED die 22 according to the actual needs of the light emitting device 2. Of course, in other embodiments, it is possible to not configure the reflective structure or to configure the reflective structure with different shapes or aspects. The preferred embodiment of the invention does not configure the reflective structure, but this is not to limit the invention.

The second transparent layer 25 covers the optical wavelength conversion layer 24, but the aspect and shape thereof are not limited. The first transparent layer 23 covering the LED die 22 is also not limited. They can have the function of condensing, dispersing or projecting according to the actual requirements, or be modified based on the applied lightings. As shown in FIG. 5A, the second transparent layer 25 has a convex surface. As shown in FIG. 5B, the second transparent layer 25a has a planar surface. As shown in FIG. 5C, the second transparent layer 25b has a concave surface. In addition, the second transparent layers 25-25b can comprise silicon gel, epoxy, a mixture of silicon gel and epoxy, a polymer material, glass, or any other transparent materials. Besides, the first transparent layer 23, the optical wavelength conversion layers 24-24b and the LED die 22 of FIGS. 5A-5C have the same features as the first transparent layers 23-23b, the optical wavelength conversion layer 24 and the LED die 22 of FIGS. 4A-4C, so the detailed description thereof will be omitted.

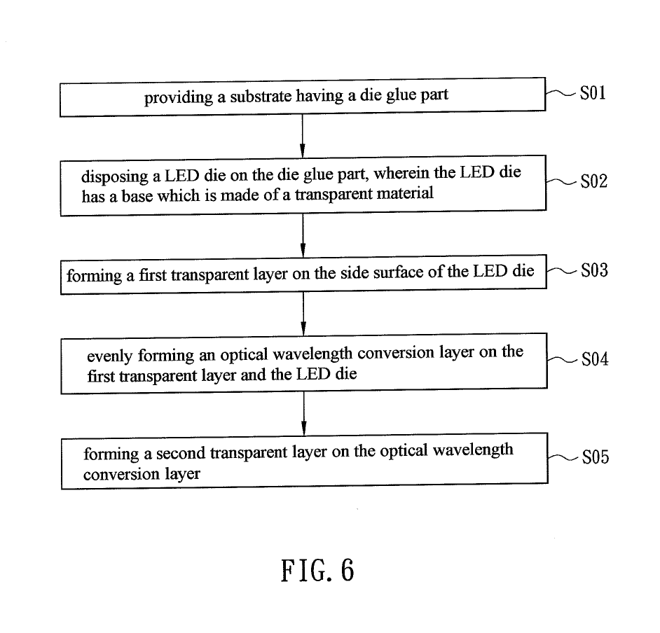

FIG. 6 is a flow chart of a manufacturing method of a light emitting device 2 according to a preferred embodiment of the invention. The manufacturing method of the embodiment includes the following steps S01 to S05.

Referring to FIG. 6 in view of FIG. 2, the first step S01 is to provide a substrate 21, which has a die glue part 211 located at the center of the top surface of the substrate 21. The substrate 21 further has two electrode connecting elements 212 and 213, a first electrode 214 and a second electrode 215. The electrode connecting elements 212 and 213 pass through the substrate 21 for electrically connecting the first electrode 214 and the second electrode 215 to the bottom surface of the substrate 21. The material of the substrate 21 can include aluminum oxide, aluminum nitride, silicon carbide, silicon substrate, copper metal or alloy, aluminum metal or alloy, a metal-core printed circuit board, a glass fiber epoxy substrate (e.g. flame retardant type (FR4 or FR5) substrate), or ceramic material (e.g. direct bond copper ceramic material).

Referring to FIG. 6 in view of FIG. 3A, the step S02 is to dispose a LED die 22 on the die glue part 211. The LED die 22 has a base 222 which is made of a transparent material such as sapphire, aluminum oxide, glass, silicon dioxide, or silicon carbide. The LED die 22 further includes a first electrode 221, an epitaxial layer 223 and a second electrode 224. The first electrode 221 and the second electrode 224 are disposed on the bottom surface of the epitaxial layer 223, and the base 222 is disposed on the epitaxial layer 223.

Next, the step S03 is to form a first transparent layer 23 on the side surface of the LED die 22. At this step S03, the first transparent layer 23 can be formed by a gluing process, a screen printing process, a spraying process, a deposition process, a molding process, or other method. The first transparent layer 23 covers the side surface of the LED die 22 in a triangle or triangle-like cross-sectional shape. The material of the first transparent layer 23 includes silicon gel, epoxy, a mixture of silicon gel and epoxy, a polymer material, glass, or any other transparent material.

Then, the step S04 is to evenly form an optical wavelength conversion layer 24 on the first transparent layer 23 and the LED die 22. Herein, the optical wavelength conversion layer 24 is evenly formed on the LED die 22 and the first transparent layer 23 by a gluing process, a screen printing process, a spraying process, a deposition process, a molding process, or any other proper method. Besides, the optical wavelength conversion layer 24 further comprises optical wavelength conversion particles, which comprise YAG (yttrium aluminum garnet) phosphor, silicate phosphor, TAG (terbium, aluminum garnet) phosphor, oxide phosphor, nitride phosphor, aluminum oxide phosphor, or any other phosphor or material with optical wavelength conversion function.

Finally, the step S05 is to form a second transparent layer 25 on the optical wavelength conversion layer 24. Herein, the second transparent layer 25 is formed on the optical wavelength conversion layer 24 by a gluing process, a screen printing process, a spraying process, a deposition process, a molding process, or any other proper method. The second transparent layer 25 can have a convex surface, a planar surface, or a concave surface. In addition, the material of the second transparent layer 25 can comprise silicon gel, epoxy, a mixture of silicon gel and epoxy, a polymer material, glass, or a transparent material.

FIGS. 4A to 4C are schematic diagrams showing the first transparent layer of the invention covering the LED die of different aspects. The first transparent layer 23 covers, for example but not limited to, the side surface of the LED die 22. Similarly, the second transparent layer 25 can be formed in various aspects (see FIGS. 5A to 5C) depending on the actual needs. In order to clarify the display and illustration, some elements are not shown in the figures, and these figures are used for reference instead of limitation.

As shown in FIG. 4A, the first transparent layer 23 covers the LED die 22, and has a part covering the side surface of the LED die 22 in a triangle or triangle-like cross-sectional shape. In addition, the optical wavelength conversion layer 24 evenly covers the first transparent layer 23.

As shown in FIG. 4B, the boundary of the first transparent layer 23a comprises the side surface of the LED die 22 and the top surface of the substrate 21, thereby forming a triangle or triangle-like cross-sectional shape on the side of the LED die 22. Thus, the optical wavelength conversion layer 24a can evenly cover the first transparent layer 23a and the LED die 22.

As shown in FIG. 4C, the boundary of the first transparent layer 23b comprises the outer surface and the bottom surface of the LED die 22, thereby forming a trapezoid or trapezoid-like cross-sectional shape on the side and top surfaces of the LED die 22. Thus, the optical wavelength conversion layer 24b can evenly cover the first transparent layer 23b.

In summary, the light emitting device and manufacturing method of the invention are suitable for the LED die with a transparent base. The first transparent layer covers the side surface of the LED die so that the optical wavelength conversion layer can evenly cover the first transparent layer and the top surface of the LED die. Thus, the light paths of the light beams emitted from the front and lateral sides of the LED die pass through the optical wavelength conversion layer are even so that they can be well mixed to provide a good optical light mixing effect and better uniformity and unity of the optical color expression.

Compared with the conventional art, the optical wavelength conversion layer of the invention can be evenly disposed so that the problem of bad uniformity and unity of the optical color expression can be solved. In addition, the possible color halo effect caused by the conventional light emitting apparatus cooperating with other optical lenses can also be prevented. Moreover, since the base of the LED die is made of transparent material, the material cost of the LED die can have more competitive than the LED die with the base made of non-transparent material.

Although the present invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the present invention.

What is claimed is:

1. A light emitting device, comprising:
a substrate having a die glue part;
a LED die disposed on the die glue part and having a base which is made of a transparent material;
a first transparent layer disposed on a side surface of the LED die;
an optical wavelength conversion layer evenly formed on the first transparent layer and the LED die; and
a second transparent layer formed on the optical wavelength conversion layer.

2. The light emitting device of claim 1, wherein the material of the substrate comprises aluminum oxide, aluminum nitride, silicon carbide, silicon substrate, copper metal or alloy, aluminum metal or alloy, a metal-core printed circuit board, a glass fiber epoxy substrate, or ceramic material.

3. The light emitting device of claim 1, wherein the substrate further comprises a first electrode, a second electrode and an electrode connecting element, the first electrode and the second electrode are disposed on the substrate and located at two sides of the die glue part, the LED die is electrically connected to the first electrode and the second electrode, the electrode connecting element passes through the substrate for electrically connecting the first electrode and the second electrode to a bottom surface of the substrate.

4. The light emitting device of claim 1, wherein the LED die has a horizontal structure, a flip-chip structure, or a flip-chip-like structure.

5. The light emitting device of claim 1, wherein the base comprises sapphire, aluminum oxide, glass, silicon dioxide, silicon carbide, or a transparent material.

6. The light emitting device of claim 1, wherein the first transparent layer covers the LED die and has a part covering the side of the LED die in a triangle or triangle-like cross-sectional shape.

7. The light emitting device of claim 1, wherein the first transparent layer is formed on the side surface of the LED die and the top surface of the substrate, thereby forming a triangle or triangle-like cross-sectional shape on the side of the LED die.

8. The light emitting device of claim 1, wherein the first transparent layer is formed on the outer surface and the bottom surface of the LED die, thereby forming a trapezoid or trapezoid-like cross-sectional shape on the side of the LED die.

9. The light emitting device of claim 1, wherein the first transparent layer covers the LED die.

10. The light emitting device of claim 1, wherein the first transparent layer comprises silicon gel, epoxy, a mixture of silicon gel and epoxy, a polymer material, glass, or a transparent material.

11. The light emitting device of claim 1, wherein the optical wavelength conversion layer further comprises optical wavelength conversion particles.

12. The light emitting device of claim 11, wherein the optical wavelength conversion particles comprise yttrium aluminum garnet (YAG) phosphor, silicate phosphor, terbium, aluminum garnet (TAG) phosphor, oxide phosphor, nitride phosphor, aluminum oxide phosphor, or any other phosphor or material with optical wavelength conversion function.

13. The light emitting device of claim 1, wherein the second transparent layer comprises silicon gel, epoxy, a mixture of silicon gel and epoxy, a polymer material, glass, or a transparent material.

14. The light emitting device of claim 1, wherein the second transparent layer has a convex surface, a planar surface, or a concave surface.

15. The light emitting device of claim 1, wherein the LED die emits visible light or invisible light.

16. The light emitting device of claim 1, wherein the substrate has a reflective structure located at the side of the top surface of the substrate.

17. A manufacturing method of a light emitting device, comprising steps of providing a substrate having a die glue part;
disposing a LED die on the die glue part, wherein the LED die has a base which is made of a transparent material;
forming a first transparent layer on side surface of the LED die;
evenly forming an optical wavelength conversion layer on the first transparent layer and the LED die; and
forming a second transparent layer on the optical wavelength conversion layer.

18. The method of claim 17, wherein the first transparent layer covers the LED die and has a part covering the side of the LED die in a triangle or triangle-like cross-sectional shape.

19. The method of claim 17, wherein the first transparent layer is formed on the side surface of the LED die and the top surface of the substrate, thereby forming a triangle or triangle-like cross-sectional shape covering on the side of the LED die.

20. The method of claim 17, wherein the first transparent layer is formed on the outer surface and the bottom surface of the LED die, thereby forming a trapezoid or trapezoid-like cross-sectional shape on the side of the LED die.

21. The method of claim 17, further comprising a step of forming the first transparent layer on the LED die.

22. The method of claim 17, wherein the first transparent layer is formed by a gluing process, a screen printing process, a spraying process, a deposition process, or a molding process.

23. The method of claim 17, wherein the photo wavelength conversion layer is evenly formed on the LED die and the first transparent layer by a gluing process, a screen printing process, a spraying process, a deposition process, or a molding process.

24. The method of claim 17, wherein the second transparent layer is formed on the optical wavelength conversion layer by a gluing process, a screen printing process, a spraying process, a deposition process, or a molding process.
